(19) United States
(12) Patent Application Publication
(10) Pub. No.: US 2026/0190558 A1
(43) Pub. Date: Jul. 2, 2026

(54) SEMICONDUCTOR DEVICE

(71) Applicant: EPISTAR CORPORATION, Hsinchu (TW)

(72) Inventors: Chih-Ming WANG, Hsinchu (TW); Zhen-Kai KAO, Hsinchu (TW); Yu-Chi WANG, Hsinchu (TW); Min-Hsun HSIEH, Hsinchu (TW); Shao-You DENG, Hsinchu (TW); Shih-An LIAO, Hsinchu (TW); Hsin-Hua LI, Hsinchu (TW)

(21) Appl. No.: 19/417,799

(22) Filed: Dec. 12, 2025

(30) Foreign Application Priority Data
Dec. 31, 2024 (TW) 113151640

(51) Int. Cl. H10H 20/857; H10H 20/831

(52) U.S. Cl. CPC H10H 20/857; H10H 20/831

(57) ABSTRACT

A semiconductor device comprises a light-emitting layer comprising a first side and a second side opposite to each other; and a first electrode structure disposed on the first side, having a first conductivity type, and comprising a first conductive bump which comprises a ridge portion.

### REFERENCE TO RELATED APPLICATION

This application claims the right of priority based on TW Application Serial No. 113151640, filed on Dec. 31, 2024, and the content of which is hereby incorporated by reference in its entirety.

### TECHNICAL FIELD

The application relates to a semiconductor device, and more particularly to an electrode structure of an optoelectronic semiconductor device.

### DESCRIPTION OF BACKGROUND ART

A light-emitting diode (LED) is a type of optoelectronic semiconductor device that possesses favorable characteristics such as low power consumption, low heat generation, long operational lifetime, vibration resistance, compact size, and fast response speed, and is therefore suitable for various lighting and display applications. An LED chip is typically electrically connected to an external circuit via conductive bumps. However, since the conductive bump generally has an arcuate profile, the LED chip may become tilted on the external circuit, thereby causing failure in the electrical connection.

### SUMMARY OF THE APPLICATION

In view of the foregoing, the embodiments of the present disclosure provide a semiconductor device having an electrode structure capable of preventing the semiconductor device from being tilted on an external circuit, thereby improving the manufacturing yield and the reliability.

According to an embodiment of the present disclosure, the semiconductor device comprises a light-emitting layer and a first electrode structure. The light-emitting layer comprises a first side and a second side opposite to each other. The first electrode structure is disposed on the first side, has a first conductivity type, and comprises a first conductive bump which comprises a ridge portion.

According to an embodiment of the present disclosure, the semiconductor device comprises the light-emitting layer and the first electrode structure. The light-emitting layer comprises the first side and the second side opposite to each other. The first electrode structure is disposed on the first side, has a first conductivity type, and comprises a first conductive bump and a second conductive bump separated from each other. In a cross-sectional view, the first conductive bump comprises a first apex, the second conductive bump comprises a second apex, and the first apex and the second apex are substantially located at the same elevation.

### BRIEF DESCRIPTION OF THE DRAWINGS

FIG. 1 illustrates a cross-sectional schematic view of the semiconductor device according to some embodiments of the present disclosure.

FIG. 2 illustrates a cross-sectional schematic view of the semiconductor device after being transferred according to some embodiments of the present disclosure.

FIGS. 3, 4, 5, 6, and 7 illustrate the top schematic views and the corresponding cross-sectional schematic views of the semiconductor device according to some embodiments of the present disclosure.

FIG. 8 illustrates a top schematic view of the semiconductor device according to some embodiments of the present disclosure.

FIG. 9 illustrates a top schematic view of the semiconductor device according to other embodiments of the present disclosure.

FIG. 10 illustrates a cross-sectional schematic view of the semiconductor device according to some embodiments of the present disclosure.

FIGS. 11, 12, 13, 14, and 15 illustrate the top schematic views and the corresponding partial cross-sectional schematic views of the semiconductor device according to some embodiments of the present disclosure.

FIG. 16 illustrates a partial cross-sectional schematic view of the semiconductor device according to some embodiments of the present disclosure.

### DETAILED DESCRIPTION OF PREFERRED EMBODIMENTS

The present disclosure provides several different embodiments that may be used to implement various features of the present disclosure. For the sake of simplicity, the present disclosure also describes examples of specific components and arrangements. The purpose of providing these embodiments is merely illustrative and is not intended to impose any limitation. Various embodiments in the present disclosure may use repeated reference numerals and/or textual annotations. The use of such repeated reference numerals and annotations is intended to make the description more concise and clear, and is not intended to indicate any relationship between different embodiments and/or configurations.

In addition, spatially relative terms used in the present disclosure, such as “beneath,” “lower,” “below,” “above,” “upper,” “top,” “bottom,” and similar terms, are used for ease of description to describe the relative relationship between one element or feature and another (or multiple) element(s) or feature(s) in the figures. Apart from the orientation shown in the figures, these spatially relative terms are also used to describe the orientation of the elements in use and during operation. As the orientation of the elements changes (e.g., rotated by 90 degrees or to other orientations), the corresponding spatial descriptions are to be interpreted in a similar manner.

Although the present disclosure uses the terms first, second, third, and so forth to describe elements, components, regions, layers, and/or sections, it should be understood that such elements, components, regions, layers, and/or sections are not to be limited by these terms. These terms are only used to distinguish one element, component, region, layer, and/or section from another, and do not imply any sequential order, nor do they indicate the arrangement order between the elements or the sequence in manufacturing processes. Therefore, without departing from the scope of the specific embodiments of the present disclosure, an element, component, region, layer, or section described as “first” herein may also be referred to as a “second” element, component, region, layer, or section.

The terms “about” or “substantially” as referred to in the present disclosure generally indicate within 20% of a given value or range, preferably within 10%, more preferably within 5%, or within 3%, 2%, 1%, or 0.5%. It should be noted that the numerical values provided in the specification are approximate values, meaning that even in the absence of explicit use of the terms “about” or “substantially,” such meanings may be implied.

The terms “coupled,” “coupling,” or “electrically connected” as referred to in the present disclosure comprise any direct or indirect electrical connection means. For example, when the text describes a first component as being coupled to a second component, it means that the first component may be directly electrically connected to the second component, or indirectly electrically connected to the second component via other devices or connecting means.

Although the following description of the present disclosure is provided using specific embodiments, the principles of the present disclosure may also be applied to other embodiments. Furthermore, to facilitate understanding of the present disclosure, certain details may be omitted.

The semiconductor device of the present disclosure is applicable to vertical and horizontal light-emitting diode structures, wherein the electrode structure comprises one or more conductive bumps. A conductive bump comprises a ridge portion, and multiple conductive bumps have at least two apices, two ridge portions, or a combination of apices and ridge portions located at the same elevation. When the semiconductor device is bonded to a carrier substrate, the conductive bumps in some embodiments of the present disclosure can allow the semiconductor device to stably stand on the carrier substrate and avoid tilting, thereby improving manufacturing yield and reliability.

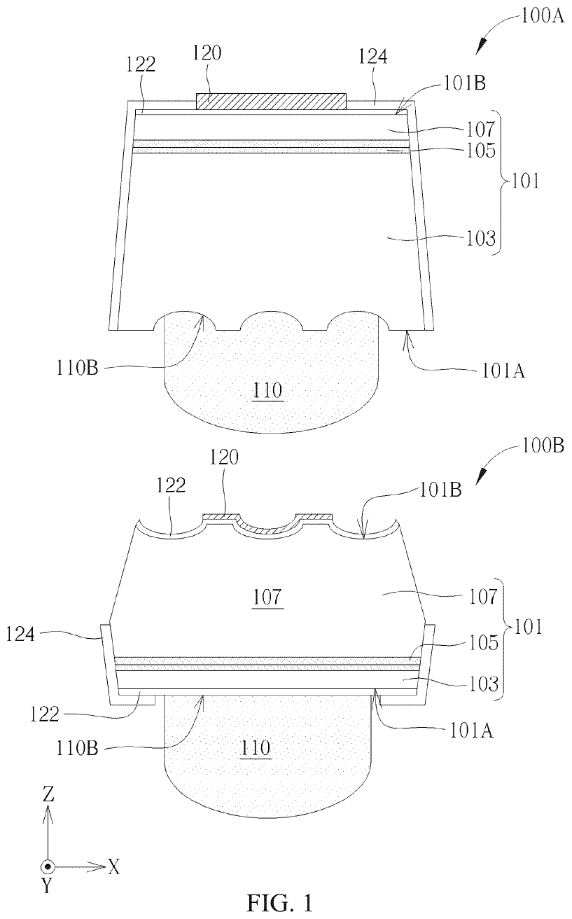

FIG. 1 illustrates a cross-sectional schematic view of the semiconductor devices 100A and 100B according to some embodiments of the present disclosure. Both of the semiconductor devices 100A and 100B comprise a vertical light-emitting diode structure (i.e., two electrodes of opposite conductivity types are respectively disposed on the opposite sides of the active layer, as described below) and comprise a light-emitting layer 101. The light-emitting layer 101 comprises a first side 101A and a second side 101B opposite to each other. A first electrode structure 110 is disposed on the first side 101A and a second electrode structure 120 is disposed on the second side 101B. The light-emitting layer 101 comprises a first semiconductor layer 103, an active layer 105, and a second semiconductor layer 107 that are sequentially stacked.

In the semiconductor device 100A, the first semiconductor layer 103 has a first conductivity type, for example, an n-type semiconductor epitaxial layer. The second semiconductor layer 107 has a second conductivity type, for example, a p-type semiconductor layer, and the second conductivity type and the first conductivity type have different conductivity types. The active layer 105 comprises a multiple quantum well (MQW). The first electrode structure 110 has the first conductivity type, for example, n-type, and comprises a conductive bump. The second electrode structure 120 has the second conductivity type, for example, p-type, and comprises a contact pad. A transparent conductive layer 122 may be disposed between the second electrode structure 120 and the second semiconductor layer 107, and the transparent conductive layer 122 comprises indium tin oxide (ITO) or indium zinc oxide (IZO). A passivation layer 124 covers the side surfaces and the lower surface of the light-emitting layer 101 and exposes the second electrode structure 120, and the passivation layer 124 comprises silicon oxide, silicon nitride, silicon oxynitride, or other electrically insulating materials.

In the semiconductor device 100B, the first semiconductor layer 103 is a p-type semiconductor layer, the second semiconductor layer 107 is an n-type semiconductor layer, and the active layer 105 comprises the multiple quantum well (MQW). The first electrode structure 110 has p-type conductivity and comprises a conductive bump. The second electrode structure 120 has n-type conductivity and comprises a contact pad. A transparent conductive layer 122 may be disposed between the first electrode structure 110 and the first semiconductor layer 103, between the second electrode structure 120 and the second semiconductor layer 107, or at both of the aforementioned locations. The passivation layer 124 covers part of the side surfaces of the light-emitting layer 101 and the first side 101A and exposes the first electrode structure 110.

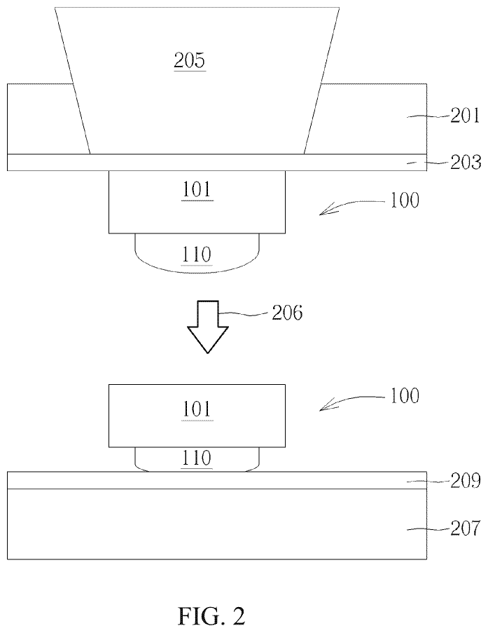

FIG. 2 illustrates a cross-sectional schematic view of a semiconductor device 100 after being transferred according to some embodiments of the present disclosure. The semiconductor device 100 may be, for example, the semiconductor device 100A or 100B as shown in FIG. 1. For simplicity of illustration, FIG. 2 only depicts the light-emitting layer 101 and the first electrode structure 110 of the semiconductor device 100, other features can be referenced to FIG. 1. Furthermore, FIGS. 1 and 2 only depict simplified schematic diagrams of the first electrode structure 110, the detailed top and cross-sectional views of the first electrode structure 110 can be referenced to the subsequent figures and descriptions. First, a laser de-bond film 203 is provided to temporarily fix the semiconductor device 100 onto a first carrier substrate 201, and the first electrode structure 110 is spaced apart from the first carrier substrate 201. After irradiated by a laser 205, the semiconductor device 100 is released from the laser de-bond film 203, and is transferred and bonded to a second carrier substrate 207 via the transfer and bonding steps 206, wherein the first electrode structure 110 is fixed on an adhesive film 209. In some embodiments of the present disclosure, the conductive bumps of the first electrode structure 110 allow the semiconductor device 100 to be stably fixed on the adhesive film 209 without tilting after the bonding, thereby improving the manufacturing yield and the reliability thereof.

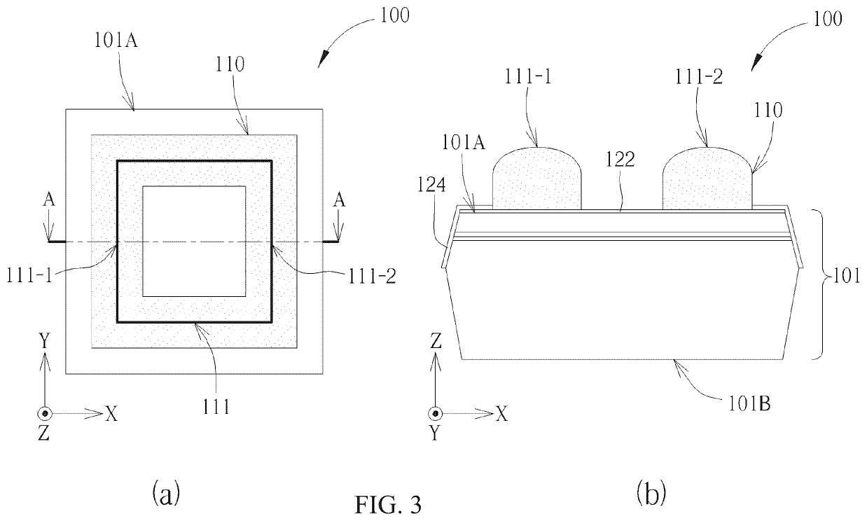

FIG. 3 illustrates a top view (a) and a cross-sectional view (b) along the line A-A of the top view of the semiconductor device 100 according to an embodiment of the present disclosure. The semiconductor device 100 comprises a vertical light-emitting diode structure, for example, the semiconductor device 100A or 100B of FIG. 1. For simplicity, the cross-sectional view does not show the second electrode structure 120, and the semiconductor device 100B is illustrated as an example. The first electrode structure 110 of the semiconductor device 100 comprises a first conductive bump. As shown in FIG. 3, in the top view (a) of the semiconductor device 100, the first conductive bump and the ridge portion 111 comprise a rectangular ring shape or a circular ring shape. As shown in the cross-sectional view (b) of FIG. 3, the top surface of the first conductive bump comprises a first protrusion 111-1 and a second protrusion 111-2 separated from each other. Both protrusions are located on the ridge portion 111, and the first protrusion 111-1 and the second protrusion 111-2 are substantially at the same elevation. In addition, the ridge portion 111 may further comprise multiple other protrusions located at the same elevation as the first protrusion 111-1 and the second protrusion 111-2. Referring to FIG. 2, the first conductive bump with the rectangular ring shape ridge portion 111 can allow the semiconductor device 100 to be stably fixed on the adhesive film 209 and without being tilted on the second carrier substrate 207.

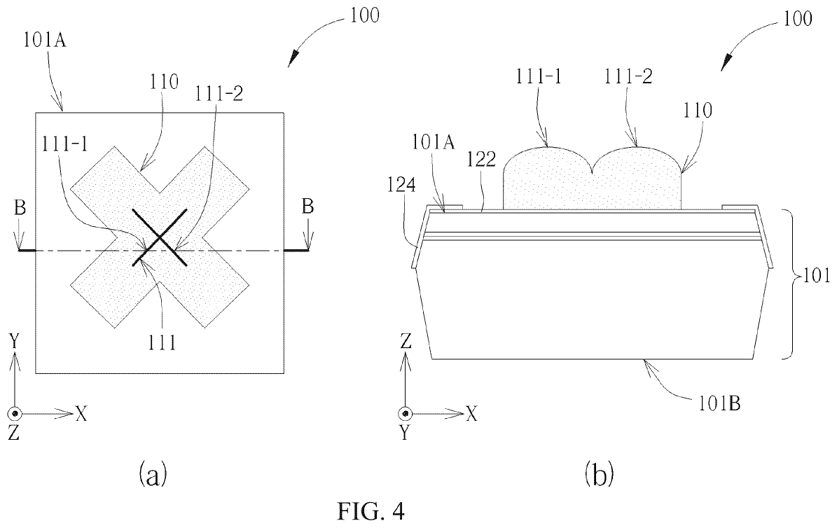

FIG. 4 illustrates a top view (a) and a cross-sectional view (b) along the line B-B of the top view of the semiconductor device 100 according to an embodiment of the present disclosure. The semiconductor device 100 is a vertical LED chip and comprises a first electrode structure 110. The first electrode structure 110 comprises a first conductive bump. As illustrated in the top view (a) of FIG. 4, the first conductive bump and the ridge portion 111 comprise an X-shaped cross configuration. As illustrated in the cross-sectional view (b) of FIG. 4, the top surface of the first conductive bump comprises a first protrusion 111-1 and a second protrusion 111-2 separated from each other. Both of the first protrusion 111-1 and the second protrusion 111-2 are located on the ridge portion 111 and are substantially at the same elevation. In addition, the ridge portion 111 may further comprise multiple protrusions located at the same elevation as the first protrusion 111-1 and the second protrusion 111-2. Referring to FIG. 2, the first conductive bump having the X-shaped cross configuration ridge portion 111 can stably fix the semiconductor device 100 on the adhesive film 209 without being tilted on the second carrier substrate 207.

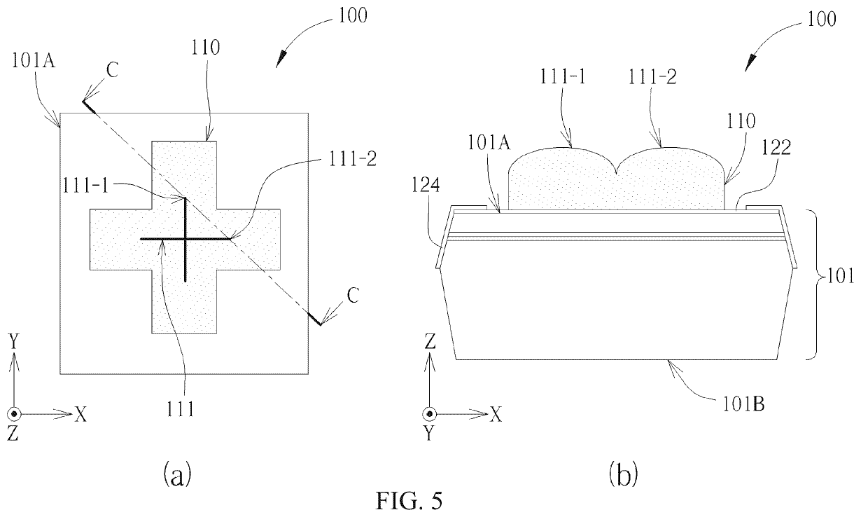

FIG. 5 illustrates a top view (a) and a cross-sectional view (b) along the line C-C of the top view of the semiconductor device 100 according to an embodiment of the present disclosure. The semiconductor device 100 is a vertical LED chip comprising the first electrode structure 110, wherein the first electrode structure 110 comprises a first conductive bump. As illustrated in the top view (a) of FIG. 5, the first conductive bump and the ridge portion 111 comprise a cross shape. As illustrated in the cross-sectional view (b) of FIG. 5, the top surface of the first conductive bump comprises a first protrusion 111-1 and a second protrusion 111-2 separated from each other. Both of the first protrusion 111-1 and the second protrusion 111-2 are located on the ridge portion 111 and are substantially at the same elevation. The ridge portion 111 may further comprise multiple other protrusions located at the same elevation as the first protrusion 111-1 and the second protrusion 111-2. Referring to FIG. 2, the first conductive bump with the cross-shaped ridge portion 111 can keep the semiconductor device 100 stably fixed on the adhesive film 209 without being tilted on the second carrier substrate 207.

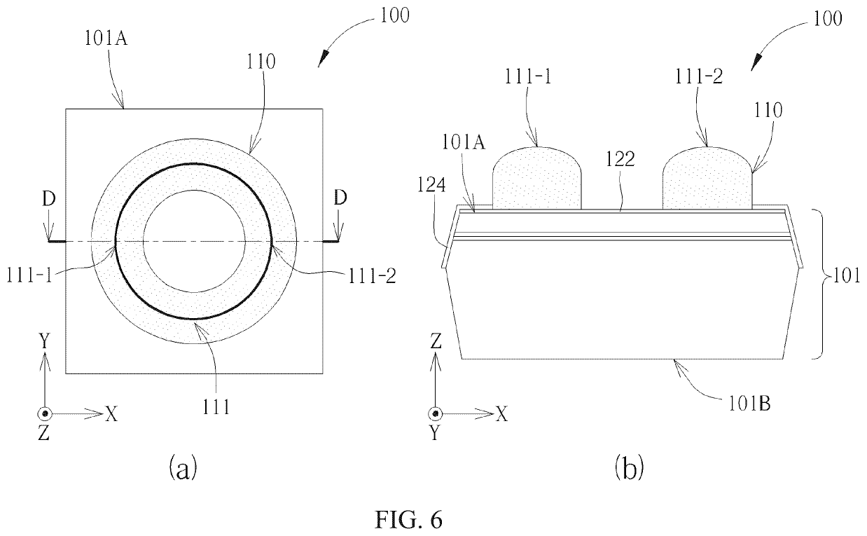

FIG. 6 illustrates a top view (a) and a cross-sectional view (b) along the line D-D of the top view of the semiconductor device 100 according to an embodiment of the present disclosure. The semiconductor device 100 is a vertical LED chip comprising the first electrode structure 110, wherein the first electrode structure 110 comprises a first conductive bump. As illustrated in the top view (a) of FIG. 6, the first conductive bump and the ridge portion 111 comprise a circular ring shape. As illustrated in the cross-sectional view (b) of FIG. 6, the top surface of the first conductive bump comprises a first protrusion 111-1 and a second protrusion 111-2 separated from each other. Both of the first protrusion 111-1 and the second protrusion 111-2 are located on the ridge portion 111 and are substantially at the same elevation. The ridge portion 111 may further comprise multiple protrusions located at the same elevation as the first protrusion 111-1 and the second protrusion 111-2. Referring to FIG. 2, the first conductive bump comprising the circular ring-shaped ridge portion 111 can keep the semiconductor device 100 stably fixed on the adhesive film 209 without being tilted on the second carrier substrate 207.

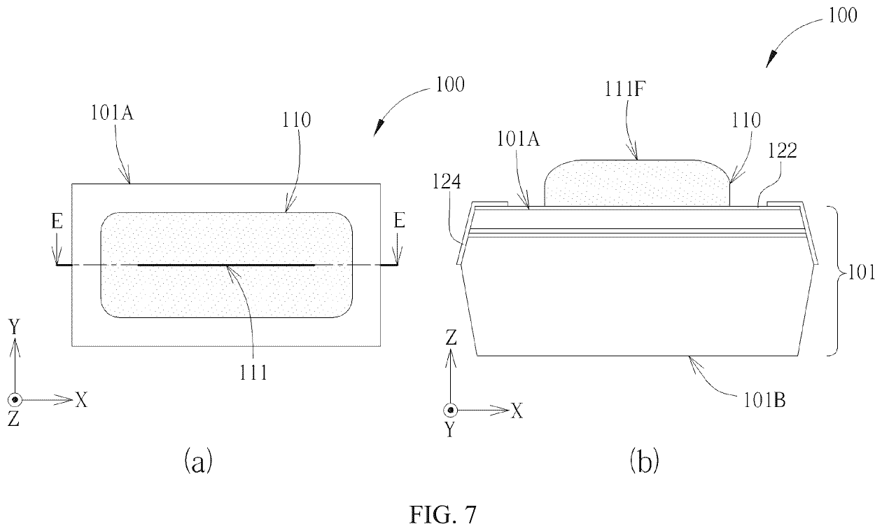

FIG. 7 illustrates a top view (a) and a cross-sectional view (b) along the line E-E of the top view of the semiconductor device 100 according to an embodiment of the present disclosure. The semiconductor device 100 is a vertical LED chip comprising the first electrode structure 110, wherein the first electrode structure 110 comprises a first conductive bump. As illustrated in the top view (a) of FIG. 7, the first conductive bump and the ridge portion 111 comprise a stripe shape. As illustrated in the cross-sectional view (b) of FIG. 7, the first conductive bump comprises a top portion 111F, and the top portion 111F is substantially at the same elevation (ex. comprising a flattop surface). Referring to FIG. 2, the first conductive bump comprising the stripe-shaped ridge portion 111 can keep the semiconductor device 100 stably fixed on the adhesive film 209 without being tilted on the second carrier substrate 207.

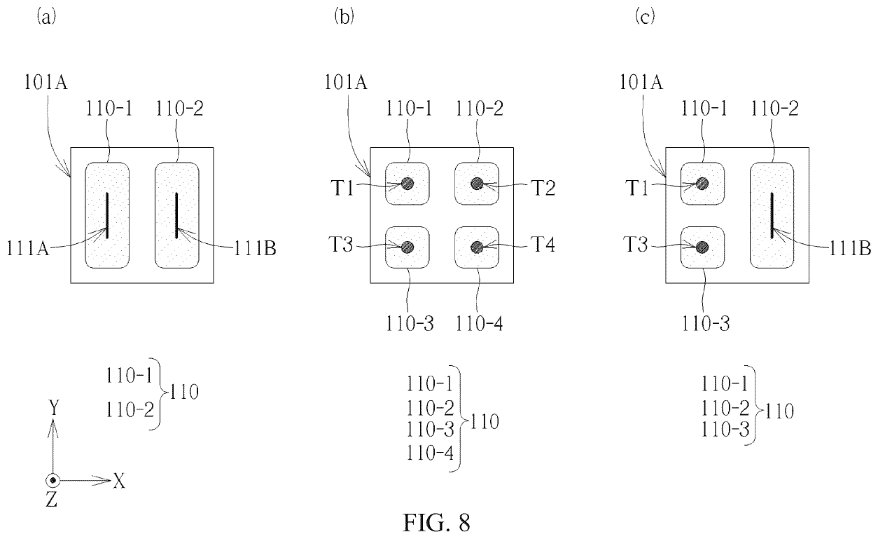

FIG. 8 illustrates the top views (a)-(c) of the semiconductor device according to some embodiments of the present disclosure. The semiconductor device comprises a vertical light-emitting diode structure, for example, the semiconductor device 100A or 100B illustrated in FIG. 1. As illustrated in the top view (a) of FIG. 8, the first electrode structure 110 comprises the first conductive bump 110-1 and the second conductive bump 110-2 separated from each other. The first conductive bump 110-1 comprises a first ridge portion 111A, the second conductive bump 110-2 comprises a second ridge portion 111B, and the first ridge portion 111A and the second ridge portion 111B are parallel to each other. In an embodiment, the first conductive bump 110-1 and the second conductive bump 110-2 may comprise the same or different shapes and/or sizes, and the first ridge portion 111A and the second ridge portion 111B may comprise the same or different shapes and/or sizes. In a cross-sectional view (not illustrated, referring to FIG. 3), the first conductive bump 110-1 comprises a first protrusion located on the first ridge portion 111A, the second conductive bump 110-2 comprises a second protrusion located on the second ridge portion 111B, and the first and second protrusions are substantially at the same elevation. In addition, the first ridge portion 111A and the second ridge portion 111B may be substantially located on the same elevation.

As illustrated in the top view (b) of FIG. 8, the first electrode structure 110 comprises a first conductive bump 110-1, a second conductive bump 110-2, a third conductive bump 110-3, and a fourth conductive bump 110-4, all separated from each other. The first conductive bump 110-1 comprises a first apex T1, the second conductive bump 110-2 comprises a second apex T2, the third conductive bump 110-3 comprises a third apex T3, the fourth conductive bump 110-4 comprises a fourth apex T4, and the first apex T1, the second apex T2, the third apex T3, and the fourth apex T4 are being substantially at the same elevation. In addition, as illustrated in the top view (b) of FIG. 8, the first conductive bump 110-1, the second conductive bump 110-2, the third conductive bump 110-3, and the fourth conductive bump 110-4 each comprises a square shape. In an embodiment, the first conductive bump 110-1, the second conductive bump 110-2, the third conductive bump 110-3, and the fourth conductive bump 110-4aq may comprise the same or different shapes and/or sizes. In another embodiment, the first electrode structure 110 may comprise other numbers of conductive bumps separated from each other, such as three conductive bumps or five or more conductive bumps.

As illustrated in the top view (c) of FIG. 8, the first electrode structure 110 comprises a first conductive bump 110-1, a second conductive bump 110-2, and a third conductive bump 110-3 separated from each other. The first conductive bump 110-1 comprises a first apex T1, the second conductive bump 110-2 comprises a second ridge portion 111B, the third conductive bump 110-3 comprises a third apex T3, and the first apex T1, the second ridge portion 111B, and the third apex T3 are substantially at the same elevation. In addition, the first conductive bump 110-1 and the third conductive bump 110-3 each comprises a square shape. In some embodiments, the first conductive bump 110-1 and the third conductive bump 110-3 may comprise the same or different shapes and/or sizes. In other embodiments, the number of the conductive bump comprising the apex is not limited to two and may be one or more than two. The second conductive bump 110-2 and the second ridge portion 111B each comprises a rectangular shape. In an embodiment, the area of the conductive bump comprising the ridge portion may be greater than the total area of the conductive bumps each comprising the apex. In another embodiment, the first conductive bump 110-1 and the third conductive bump 110-3 may be located on the same side of the second conductive bump 110-2 (as illustrated in FIG. 8(c)) or on two opposite sides (not illustrated).

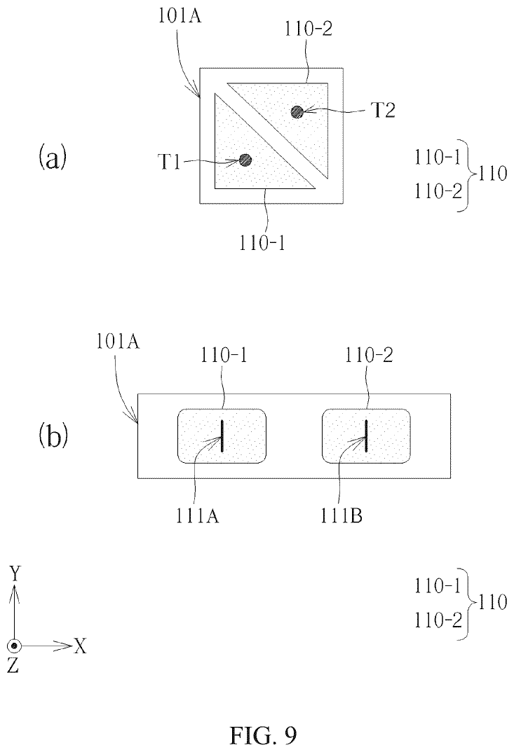

FIG. 9 illustrates the top views (a) and (b) of the semiconductor device according to other embodiments of the present disclosure. The semiconductor device comprises the vertical light-emitting diode structure, for example, the semiconductor device 100A or 100B illustrated in FIG. 1. In an embodiment, the first electrode structure 110 of the semiconductor device comprises two conductive bumps. As illustrated in the top view (a) of FIG. 9, the semiconductor device is a vertical LED chip comprising the first electrode structure 110, wherein the first electrode structure 110 comprises a first conductive bump 110-1 and a second conductive bump 110-2 separated from each other. The first conductive bump 110-1 comprises a first apex T1, the second conductive bump 110-2 comprises a second apex T2, and the first apex T1 and the second apex T2 ARE substantially at the same elevation. In addition, the first conductive bump 110-1 and the second conductive bump 110-2 each comprises a triangular shape, and the two triangles are mirror-symmetrical with respect to a diagonal line. In an embodiment, the first conductive bump 110-1 and the second conductive bump 110-2 may comprise the same or different shapes and/or sizes. Referring to FIG. 2, the first conductive bump 110-1 and the second conductive bump 110-2 respectively comprising the first apex T1 and the second spec T2 are substantially at the same elevation, which allows the semiconductor device 100 to be stably fixed on the adhesive film 209 without being tilted on the second carrier substrate 207.

As illustrated in the top view (b) of FIG. 9, the semiconductor device is a vertical LED chip comprising the first electrode structure 110, wherein the first electrode structure 110 comprises the first conductive bump 110-1 and the second conductive bump 110-2 separated from each other. The first conductive bump 110-1 comprises a first ridge portion 111A, the second conductive bump 110-2 comprises a second ridge portion 111B, and the first ridge portion 111A and the second ridge portion 111B are parallel and substantially at the same elevation. In addition, the first conductive bump 110-1 and the second conductive bump 110-2 each comprises a rectangular shape, the first ridge portion 111A and the second ridge portion 111B each comprises a stripe shape and are respectively located in the middle region of the first conductive bump 110-1 and the second conductive bump 110-2. In an embodiment, the first conductive bump 110-1 and the second conductive bump 110-2 may comprise the same or different shapes and/or sizes, and the first ridge portion 111A and the second ridge portion 111B may comprise the same or different shapes and/or sizes. In other embodiments, the first electrode structure 110 may comprise other numbers of the conductive bump comprising the ridge portion, such as three or more conductive bumps. Referring to FIG. 2, the first conductive bump 110-1 and the second conductive bump 110-2, comprising the parallel ridge portions 111A and 111B allows the semiconductor device 100 to be stably fixed on the bonding adhesive 209 without being tilted on the second carrier substrate 207.

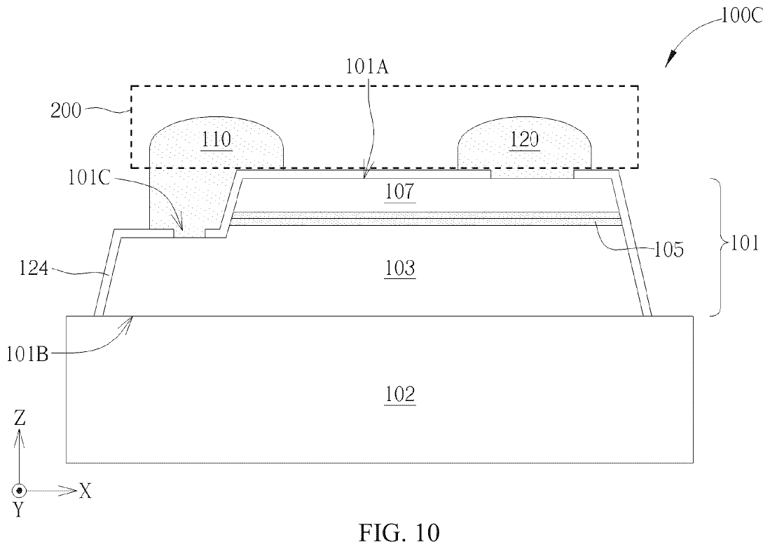

FIG. 10 illustrates a cross-sectional schematic view of a semiconductor device 100C according to some embodiments of the present disclosure. The semiconductor device 100C comprises a horizontal light-emitting diode structure and comprises a light-emitting layer 101 and a passivation layer 124. The light-emitting layer 101 comprises a first side 101A and a second side 101B opposite to each other. A mesa structure 101C is formed on the first side 101A of the light-emitting layer 101 to expose the partial surface of the first semiconductor layer 103. The light-emitting layer 101 is connected to a substrate 102 on the second side 101B. The substrate 102 may be a growth substrate or a carrier substrate. The passivation layer 124 covers the upper surface and the side surfaces of the light-emitting layer 101 and extends to the mesa structure 101C. The passivation layer 124 comprises openings to expose the first semiconductor layer 103 and the second semiconductor layer 107 separately. Other details of the light-emitting layer 101 may be referenced to the related descriptions of FIG. 1. Both the first electrode structure 110 and the second electrode structure 120 of the semiconductor device 100C are disposed on the first side 101A of the light-emitting layer 101. The first electrode structure 110 has a first conductivity type and the second electrode structure 120 has a second conductivity type, wherein the second conductivity type and the first conductivity type have different conductivity types. The first electrode structure 110 is electrically connected to the first semiconductor layer 103 and the second electrode structure 120 is electrically connected to the second semiconductor layer 107. Detailed cross-sectional views of the first electrode structure 110 and the second electrode structure 120 of the various embodiments in the boxed region 200 of FIG. 10 are illustrated in subsequent figures and descriptions.

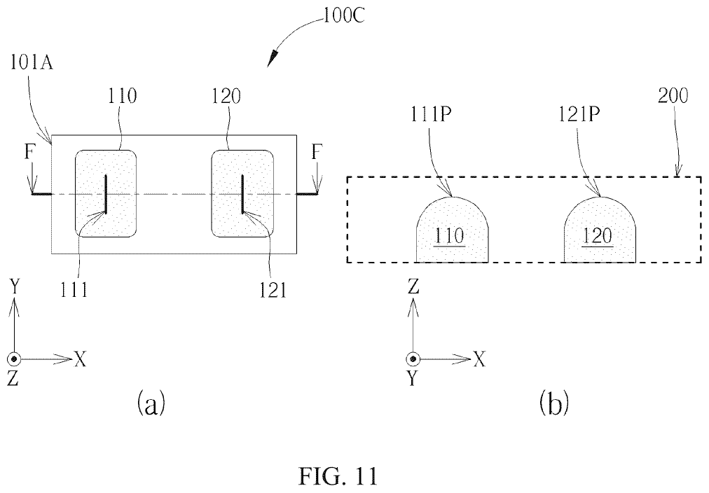

FIG. 11 illustrates a top view (a) and a cross-sectional view (b) along the line F-F of top view of the first and second electrode structures 110 and 120 of the semiconductor device 100C as illustrated in FIG. 10 according to an embodiment of the present disclosure. The semiconductor device 100C is a horizontal LED chip comprising a first electrode structure 110 and a second electrode structure 120. The first electrode structure 110 comprises a first conductive bump and the second electrode structure 120 comprises a second conductive bump. The first conductive bump comprises a ridge portion 111, the second conductive bump comprises a ridge portion 121, and the ridge portions 111 and 121 are parallel to each other. In addition, as illustrated in the top view (a) of FIG. 11, the first electrode structure 110 and the second electrode structure 120 each comprise the rectangular shape, and the ridge portions 111 and 121 comprise stripe shapes and are parallel to each other.

As illustrated in the cross-sectional view (b) of the electrode structures 110 and 120 of FIG. 11, the first electrode structure 110 comprises a protrusion 111P, the second electrode structure 120 comprises a protrusion 121P, and the protrusions 111P and 121P are substantially at the same elevation. In addition, the ridge portions 111 and 121 may also be located on the same elevation. Referring to FIG. 2, the first electrode structure 110 and the second electrode structure 120 having the parallel ridge portions 111 and 121 can allow the semiconductor device 100C to be stably fixed on the adhesive film 209 without being tilted on the second carrier substrate 207.

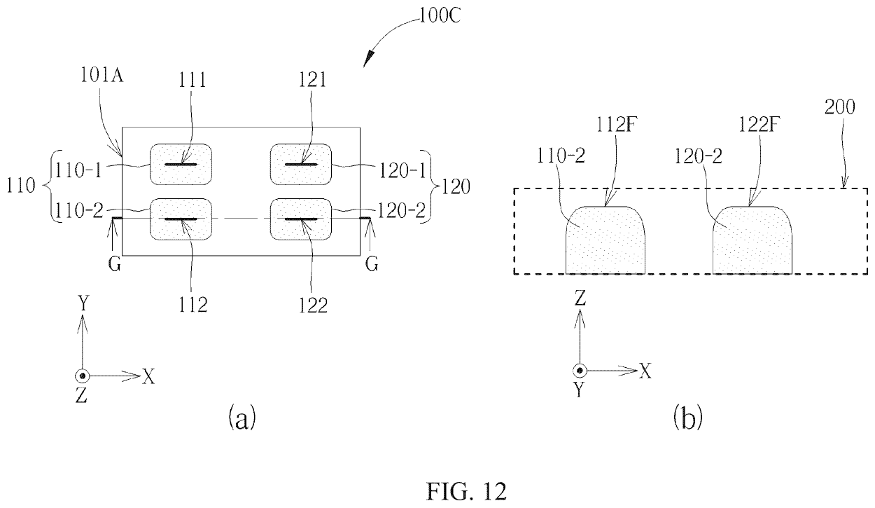

FIG. 12 illustrates a top view (a) and a cross-sectional view (b) along the line G-G of the conductive bump 110-2 and the conductive bump 120-2 of the semiconductor device 100C according to an embodiment of the present disclosure. The semiconductor device 100C comprises a first electrode structure 110 and a second electrode structure 120. The first electrode structure 110 comprises the conductive bumps 110-1 and 110-2 separated from each other, wherein the conductive bump 110-1 comprises a ridge portion 111, the conductive bump 110-2 comprises a ridge portion 112, and the ridge portions 111 and 112 are parallel to each other. The second electrode structure 120 comprises the conductive bumps 120-1 and 120-2 separated from each other, wherein the conductive bump 120-1 comprises a ridge portion 121, the conductive bump 120-2 comprises a ridge portion 122, and the ridge portions 121 and 122 are parallel to each other. In addition, as illustrated in the top view (a) of FIG. 12, the conductive bumps 110-1, 110-2, 120-1, and 120-2 each comprises a rectangular shape, and the ridge portions 111, 112, 121, and 122 each comprises a stripe shape.

As illustrated in the cross-sectional view (b) along the line G-G of FIG. 12, the ridge portion 112 of the conductive bump 110-2 comprises a top portion 112F, the ridge portion 122 of the conductive bump 120-2 comprises a top portion 122F, and the top portions 112F and 122F are substantially at the same elevation. In addition, the ridge portion 111 of the conductive bump 110-1 and the ridge portion 121 of the conductive bump 120-1 may also be located on the same elevation. Referring to FIG. 2, the conductive bumps 110-1, 110-2, 120-1, and 120-2 respectively comprising the ridge portions 111, 112, 121, and 122 allow the semiconductor device 100 to be stably fixed on the adhesive film 209 without being tilted on the second carrier substrate 207.

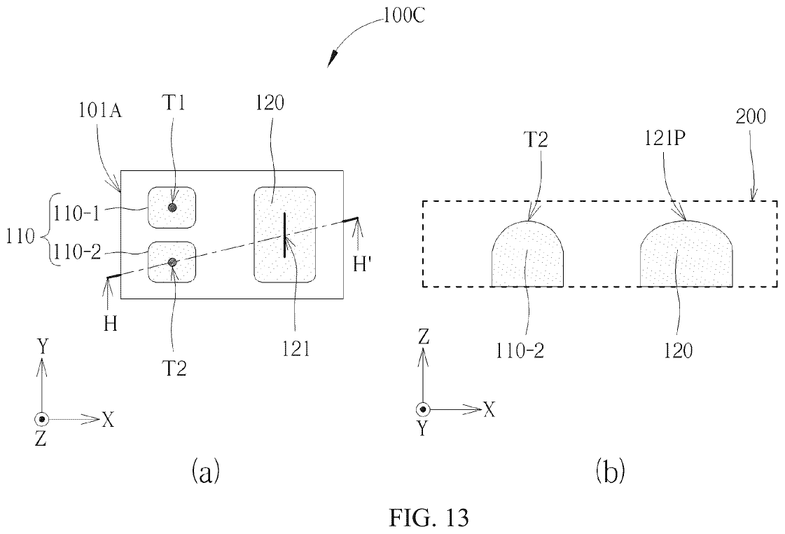

FIG. 13 illustrates a top view (a) and a cross-sectional view (b) along the line H-H′ of the conductive bump 110-2 and the second electrode structure 120 of the semiconductor device 100C according to an embodiment of the present disclosure. The semiconductor device 100C comprises a first electrode structure 110 and a second electrode structure 120. The first electrode structure 110 comprises the conductive bumps 110-1 and 110-2 separated from each other, wherein the conductive bump 110-1 comprises a first apex T1, and the conductive bump 110-2 comprises a second apex T2. Both of the conductive bumps 110-1 and 110-2 comprise the square shape, and the first apex T1 and the second apex T2 are approximately located at the central region of the conductive bumps 110-1 and 110-2, respectively. The second electrode structure 120 comprises a conductive bump comprising a ridge portion 121. As illustrated in the top view (a) of FIG. 13, the second electrode structure 120 comprises a rectangular shape, the ridge portion 121 comprises a stripe shape, and the ridge portion 121 is substantially located in the middle region of the second electrode structure 120.

As illustrated in the cross-sectional view (b) of FIG. 13, the ridge portion 121 of the second electrode structure 120 comprises a protrusion 121P, and the second apex T2 and the protrusion 121P are substantially at the same elevation. In addition, the first apex T1, the second apex T2, and the ridge portion 121 may also be located at approximately the same elevation. Referring to FIG. 2, the conductive bump 110-1 comprising the first apex T1, the conductive bump 110-2 comprising the second apex T2, and the second electrode structure 120 comprising the ridge portion 121 can allow the semiconductor device 100C to be stably fixed on the adhesive film 209 without being tilted on the second carrier substrate 207.

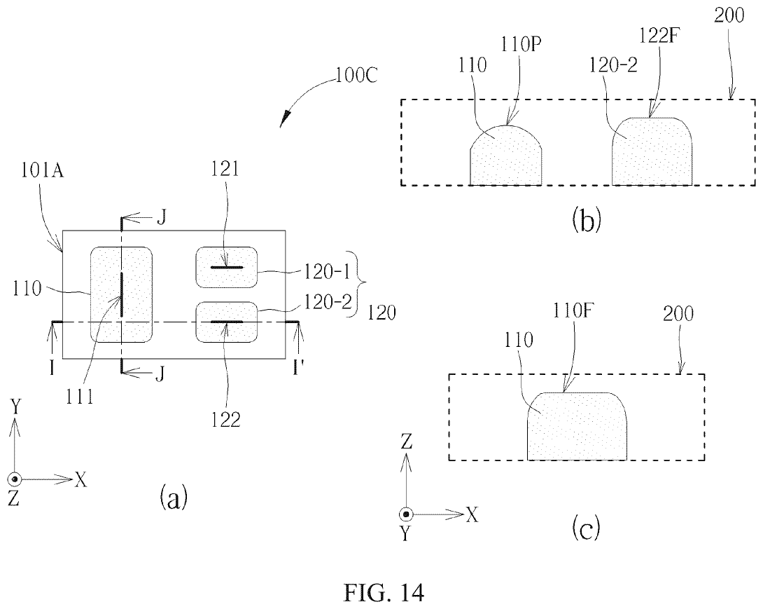

FIG. 14 illustrates a top view (a) of the semiconductor device 100C, a cross-sectional view (b) of the first electrode structure 110 and the conductive bump 120-2 along the line I-I′, and a cross-sectional view (c) of the first electrode structure 110 along the line J-J according to an embodiment of the present disclosure. The semiconductor device 100C comprises the first electrode structure 110 and the second electrode structure 120. As illustrated in the top view (a) of the semiconductor device 100C shown in FIG. 14, the first electrode structure 110 comprises a conductive bump comprising a ridge portion 111, the first electrode structure 110 comprises a rectangular shape, and the ridge portion 111 comprising a stripe shape. The second electrode structure 120 comprises the conductive bumps 120-1 and 120-2 separated from each other, wherein the conductive bump 120-1 comprises a ridge portion 121, the conductive bump 120-2 comprises a ridge portion 122, and the ridge portions 121 and 122 are parallel to each other. The conductive bumps 120-1 and 120-2 each comprises a rectangular shape, and the ridge portions 121 and 122 each comprises a stripe shape. The longitudinal direction of the ridge portion 111 of the first electrode structure 110 is different from that of the ridge portions 121 and 122 of the second electrode structure 120. For example, the longitudinal direction of the ridge portion 111 may be substantially perpendicular to that of the ridge portions 121 and 122.

As illustrated in the cross-sectional view (b) along the line I-I′ of FIG. 14, the ridge portion 111 of the first electrode structure 110 comprises a protrusion 110P, which is not the highest point of the ridge portion 111. The conductive bump 120-2 of the second electrode structure 120 comprises a top portion 122F, and the elevation of the protrusion 110P is slightly lower than that of the top portion 122F. In addition, as illustrated in the cross-sectional view (c) of FIG. 14, the first electrode structure 110 comprises a top portion 110F. In an embodiment, the ridge portion 111, the ridge portion 121 of the conductive bump 120-1, and the ridge portion 122 of the conductive bump 120-2 are located at the same elevation. Referring to FIG. 2, the first electrode structure 110 comprising the ridge portion 111, the conductive bump 120-1 comprising the ridge portion 121, and the conductive bump 120-2 comprising the ridge portion 122 can allow the semiconductor device 100 to be stably fixed on the adhesive film 209 without being tilted on the second carrier substrate 207.

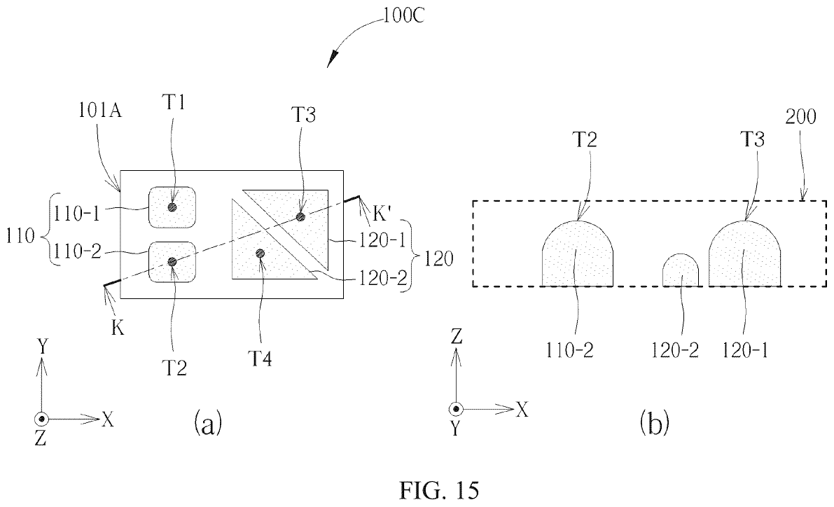

FIG. 15 illustrates a top view (a) of the semiconductor device 100C and a cross-sectional view (b) of the conductive bumps 110-2, 120-1, and 120-2 along the line K-K′ according to an embodiment of the present disclosure. The semiconductor device 100C comprises a first electrode structure 110 and a second electrode structure 120. As illustrated in the top view (a) of the semiconductor device 100C shown in FIG. 15, the first electrode structure 110 comprises the conductive bumps 110-1 and 110-2 separated from each other, wherein the conductive bump 110-1 comprises a first apex T1 and the conductive bump 110-2 comprises a second apex T2. Both of the conductive bumps 110-1 and 110-2 comprise the square shape, and the first apex T1 and the second apex T2 are located in the central region of the conductive bumps 110-1 and 110-2, respectively. The second electrode structure 120 comprises the conductive bumps 120-1 and 120-2 separated from each other, wherein the conductive bump 120-1 comprises a third apex T3 and the conductive bump 120-2 comprises a fourth apex T4. Both of the conductive bumps 120-1 and 120-2 comprise the triangular shape, and the third apex T3 and the fourth apex T4 are located near the centroid of the conductive bumps 120-1 and 120-2, respectively.

As illustrated in the cross-sectional view (b) of FIG. 15 along the line K-K′, the second apex T2 and the third apex T3 are substantially at the same elevation. In addition, the first apex T1, the fourth apex T4, the second apex T2, and the third apex T3 may also be located at the same elevation. Referring to FIG. 2, the conductive bump 110-1 comprising the first apex T1, the conductive bump 110-2 comprising the second apex T2, the conductive bump 120-1 comprising the third apex T3, and the conductive bump 120-2 comprising the fourth apex T4 can allow the semiconductor device 100 to be stably fixed on the adhesive film 209 without being tilted on the second carrier substrate 207.

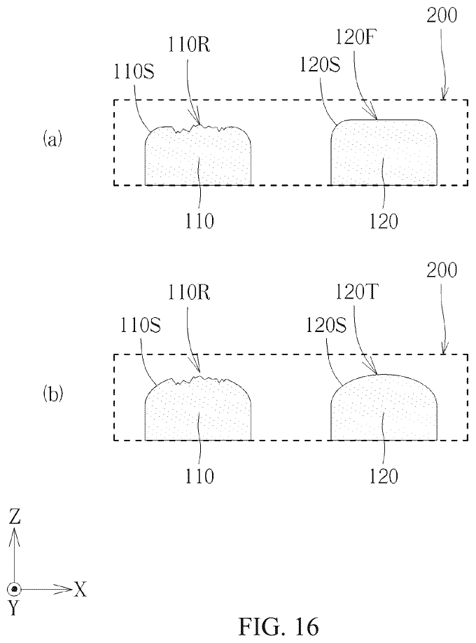

FIG. 16 illustrates the cross-sectional views (a) and (b) of the electrode structure of the semiconductor device according to some embodiments of the present disclosure. The semiconductor device comprises a horizontal light-emitting diode structure, for example, the semiconductor device 100C shown in FIG. 10. As illustrated in the cross-sectional view (a) of FIG. 16, the first electrode structure 110 comprises a first outer surface 110S and the second electrode structure 120 comprises a second outer surface 120S. The first outer surface 110S comprises a top portion 110R, the second outer surface 120S comprises a top portion 120F, and the average roughness of the top portion 110R is greater than that of the top portion 120F. In an embodiment, the top portion 110R comprises at least a protrusion located at the same elevation as the top portion 120F.

As illustrated in the cross-sectional view (b) of FIG. 16, the first electrode structure 110 comprises the first outer surface 110S and the second electrode structure 120 comprises a second outer surface 120S. The first outer surface 110S comprises a top portion 110R, the second outer surface 120S comprises an apex 120T, and the average roughness of the top portion 110R is greater than that of the second outer surface 120S. In this embodiment, the top portion 110R comprises at least a protrusion located at the same elevation as the apex 120T.

The above description is merely exemplary embodiments of the present disclosure, and any equivalent changes and modifications made in accordance with the scope of the claims of the present disclosure shall fall within the scope of the present disclosure.

What is claimed is:

1. A semiconductor device, comprising:
a light-emitting layer comprising a first side and a second side opposite to each other; and
a first electrode structure disposed on the first side, having a first conductivity type, and comprising a first conductive bump which comprises a ridge portion.

2. The semiconductor device according to claim 1, wherein, in a top view, the ridge portion comprises a shape selected from the group consisting of a rectangular ring shape, an X-shaped cross, a cross shape, a circular ring shape, or a stripe shape.

3. The semiconductor device according to claim 1, further comprising a second electrode structure disposed on the second side, and having a second conductivity type, wherein the second conductivity type and the first conductivity type have different conductivity types.

4. The semiconductor device according to claim 1, further comprising a second electrode structure disposed on the first side, and having a second conductivity type, wherein the second conductivity type and the first conductivity type have different conductivity types.

5. The semiconductor device according to claim 4, wherein the second electrode structure comprises a second conductive bump, in a cross-sectional view, the second conductive bump comprises a second outer surface, the second outer surface comprises an apex, and the ridge portion and the apex are substantially located on a same elevation.

6. The semiconductor device according to claim 4, wherein the second electrode structure comprises a second conductive bump, in a cross-sectional view, the first conductive bump comprises a first outer surface, the second conductive bump comprises a second outer surface, and an average roughness of the first outer surface is greater than an average roughness of the second outer surface.

7. A semiconductor device, comprising:
a light-emitting layer comprising a first side and a second side opposite to each other; and
a first electrode structure disposed on the first side, having a first conductivity type, and comprising a first conductive bump and a second conductive bump separated from each other,
wherein, in a cross-sectional view, the first conductive bump comprises a first apex, the second conductive bump comprises a second apex, and the first apex and the second apex are substantially located at the same elevation.

8. The semiconductor device according to claim 7, wherein in a top view, the first conductive bump comprises a first outer surface, the first outer surface comprises a first ridge portion, the second conductive bump comprises a second outer surface, the second outer surface comprises a second ridge portion, and the first ridge portion and the second ridge portion are parallel to each other.

9. The semiconductor device according to claim 7, further comprising a second electrode structure disposed on the first side or the second side and having a second conductivity type, wherein the second conductivity type and the first conductivity type have different conductivity types.

10. The semiconductor device according to claim 9, wherein the second electrode structure comprises a third conductive bump, the third conductive bump comprises a third apex, the second electrode structure is disposed on the first side, and the first apex, the second apex and the third apex are substantially located on a same elevation.
